(19) United States
(12) Patent Application Publication
(10) Pub. No.: US 2017/0303386 A1
(43) Pub. Date: Oct. 19, 2017

(54) Printed Circuit Board Integrated Radio Frequency Absorber

(71) Applicant: L-3 Communications Corporation, New York, NY (US)

(72) Inventor: Gerald COLES, Rowlett, TX (US)

(73) Assignee: L-3 Communications Corporation, New York, NY (US)

(21) Appl. No.: 15/098,533

(22) Filed: Apr. 14, 2016

(51) Int. Cl. H05K 1/02; H05K 1/18; H05K 3/30; H05K 3/40

(52) U.S. Cl. CPC H05K 1/024; H05K 3/303; H05K 3/4038; H05K 1/0216; H05K 1/181; H05K 2201/10674

(57) ABSTRACT

A printed circuit board (PCB), electronic assembly, and method are provided. A PCB adapted to receive a radio frequency (RF) chip includes one or more features that extend through at least a portion of the depth of the PCB. The features are filled with an RF absorber composite comprising a binder and an RF absorber material. The features are positioned in the PCB to reduce RF signal coupling between the RF chip and one or more metal surfaces of the PCB.

### TECHNICAL FIELD

The present application relates generally to suppression of unwanted radiated signals and, more specifically, to a printed circuit board integrated radio frequency absorber.

### BACKGROUND

Increased circuit density in electronic assemblies has driven the industry to seek new integrated circuit mounting techniques. To achieve higher density board assembly, integrated circuit dies may be mounted without a package or wire-bonds by applying an appropriate interface material or direct solder to specially designed surfaces on the die, flipping it over and eutectically attaching it to a printed circuit board (PCB) or other substrate. In radio frequency (RF) assemblies, this technique may be used to diminish an occupied surface area. Although higher densities are realized with this technique, on-die stage-to-stage and power supply isolation is more difficult to achieve, especially at very high frequencies. As RF/Microwave chip density, as well as designed frequency and transmitted power levels, increase, the amount of isolation in a reduced area becomes problematic. New methods and techniques are needed to improve this isolation.

As shown in FIG. 1, a system 100 may include a die 102 having a ground metal side attached to a PCB 104 by conductive material 106, which may be silver-bearing epoxy, a eutectic material, or by some other suitable material. Wires 108 or ribbons are bonded to pads 110 on the PCB and to pad surfaces on a top surface of the die to couple the die to the rest of the board circuitry.

As shown in FIG. 2, a system 200 may include a die 202 mounted to a PCB 204 by attaching solder balls 212, silver-bearing epoxy, or other suitable conductive material to pads on a top surface of the die 202, flipping the die 202 over, and bonding the solder balls 212 to pads on the PCB 204. Such a mounting configuration may be referred to as a flip-chip configuration. Such a flip-chip die die may be treated as a conventional surface mount component that is directly soldered onto the board. An underfill material 214 is typically flowed under the die 202 after it is bonded to the PCB 204. The underfill material 214 provides mechanical support to the die 202, which may be a physically fragile device.

As shown in FIG. 3, in conventional, “un-flipped” use, a desired amount of isolation between internal circuits may be designed into the electronic assembly. A reflective surface 316 that might compromise this isolation may be kept at a desired distance (distance D) away from a die 102. Such current design practices diminish the chances of feedback.

As shown in FIG. 4, with flip-chip mounting, a reflective surface 418 (which may be any of numerous metal surfaces of the PCB) has now been placed in very close proximity (distance d) to the top surface of the die 202. The reflective surface 418 can conduct signals that radiate from the internal circuitry of the die 202 and couple them to other areas within die 202 or to other circuits adjacent to the die, which may result in unstable operation (e.g., oscillation) of the die 202 and/or nearby circuits.

While the underfill material 214 is present between the die 202 and the reflective surface 418, it is not desirable to attempt to dampen the RF signal reflections between the die 202 and the reflective surface 418 by formulating the underfill 214 as an RF absorbent material. Such a material would also have the undesirable effect of absorbing and otherwise interfering with RF signals in and between the solder balls 212 and their associated solder pads on the PCB 204.

### SUMMARY

In a first embodiment, a PCB adapted to receive an RF chip includes one or more features that extend through at least a portion of the depth of the PCB. The features are filled with an RF absorber composite comprising a binder and an RF absorber material. The features are positioned in the PCB to reduce RF signal coupling between the RF chip and one or more metal surfaces of the PCB.

In a second embodiment, an electronic assembly includes a PCB and an RF chip mounted to the PCB in a flip-chip configuration. The PCB includes one or more features that extend through at least a portion of the depth of the PCB. The features are filled with an RF absorber composite comprising a binder and an RF absorber material. The features are positioned in the PCB to reduce RF signal coupling between the RF chip and one or more metal surfaces of the PCB.

In a third embodiment, a method for fabricating a PCB for use with an RF chip includes forming one or more cavities in at least one substrate of a PCB. The method further includes filling the cavities with an RF absorber composite comprising a binder and an RF absorber material. The cavities are positioned in the PCB substrate to reduce RF signal coupling between the RF chip and one or more metal surfaces of the PCB.

Before undertaking the DETAILED DESCRIPTION below, it may be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, such a device may be implemented in hardware, firmware or software, or some combination of at least two of the same. It should be noted that the functionality associated with any particular controller may be centralized or distributed, whether locally or remotely. Definitions for certain words and phrases are provided throughout this patent document, those of ordinary skill in the art should understand that in many, if not most instances, such definitions apply to prior, as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIGS. 1 and 2 illustrate systems having circuit dies mounted according to conventional techniques.

FIGS. 3 and 4 illustrate the systems of FIGS. 1 and 2 and associated reflective surfaces.

FIGS. 5A and 5B illustrate schematic hidden line top and cutaway side views of a circuit die and printed circuit board (PCB) according to one embodiment of the disclosure.

FIG. 6 illustrates an interior view of a system comprising a flipped circuit die and underlying conventional PCB.

FIG. 7 presents simulated frequency responses of four characteristics of the system of FIG. 6.

FIG. 8 illustrates an interior view of a system comprising a circuit die and underlying PCB having a sheet of RF absorbent material according to one embodiment of the disclosure.

FIG. 9 presents simulated frequency responses of four characteristics of the system of FIG. 8.

FIG. 10 illustrates an interior view of an electronic assembly comprising a circuit die and underlying PCB according to another embodiment of the disclosure.

FIG. 11 presents simulated frequency responses of four characteristics of the system of FIG. 10.

### DETAILED DESCRIPTION

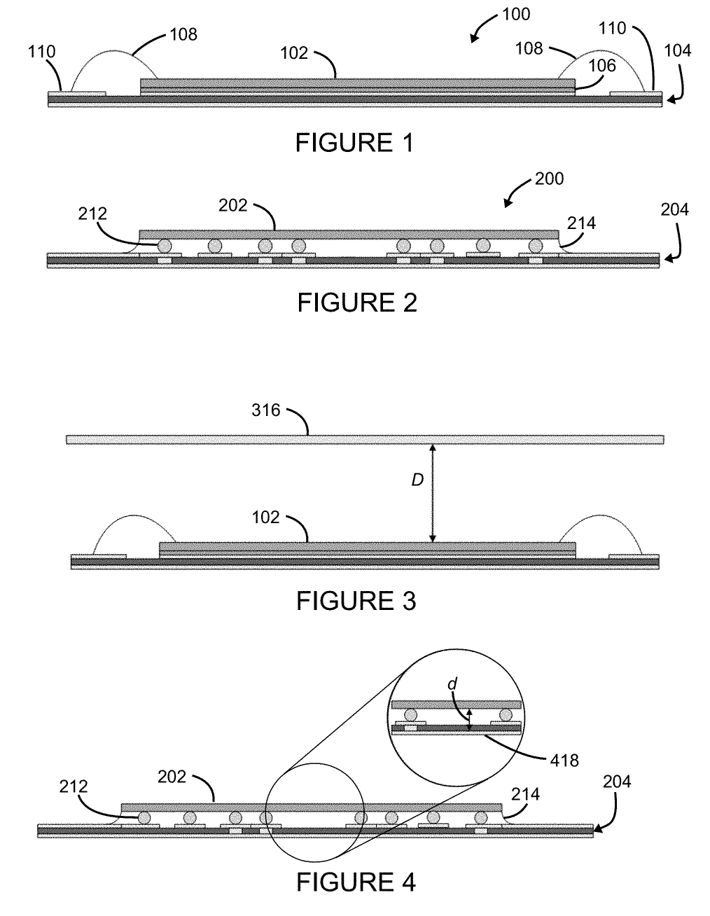

FIGS. 1 through 11, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged printed circuit board integrated radio frequency absorber.

This invention provides a means of suppressing unwanted radio frequency (RF) coupling between various stages of flip-chip designs by filling a series of un-plated vias or other features in a printed circuit board (PCB) directly beneath the chip with a binder material mixed with an RF absorber. Such a chip may also be referred to as an integrated circuit (IC) or a circuit die (die). The techniques of the present disclosure are preferably applied to chips wherein at least part of the circuitry in the chip operates at RF frequencies (as defined below). Such chips may be referred to as RF chips or RF dies.

The term “radio frequency” typically indicates frequencies in the range from 3 kilohertz (kHz) to 300 gigahertz (GHz). The techniques of the present disclosure are most effective in the RF sub-range of 400 megahertz (MHz) to 70 GHz, but may be advantageously applied to systems operating above or below that sub-range. For the purposes of this disclosure, the term “RF” includes not only signals intended for wireless transmission and reception, but also high speed digital signals intended for wired communication. Examples of such high speed digital signals include signals operating at 10 gigabits (Gbits) and/or in the range of 5 GHz to 15 GHz.

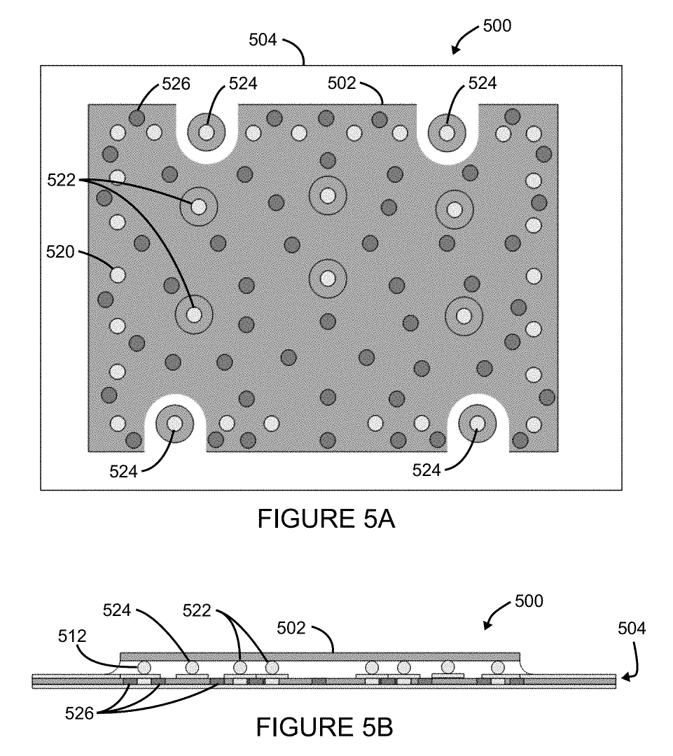

FIGS. 5A and 5B illustrate a schematic hidden line top view and a cutaway side view (respectively) of a system 500 according to one embodiment of the disclosure. The system 500 comprises a circuit die 502 and a PCB 504 that is adapted to receive the die 502. The die 502 includes connectors 520 (located in this embodiment around the periphery of the die 502) that conduct control signals, power, and ground between the die 502 and the PCB 504. The die 502 also includes ground posts 522 that provide ground connections between the die 502 and the PCB 504. The die 502 further includes RF connectors 524 that conduct RF signals into and out of the die 502 from the PCB 504.

The PCB 504 includes un-plated holes 526 (or other cavities) formed in a substrate of the PCB 504 that are filled with an RF absorber composite comprising a resin or other suitable binder containing an RF absorber material. In embodiments where resin is used, it may be cured during the manufacturing process. Examples of suitable binder material include THP-100DX1 Thermally Cured One Component Hole Fill from Taiyo America, Inc. of Carson City, Nev.; and PHP900 from SAN-EI Kagaku Co., Ltd. of Tokyo, Japan. Examples of suitable RF absorber material include MR11-0039-00 Tuned Frequency Absorber from MAST Technologies of San Diego, Calif.; ECCOSORB CR from Laird PLC of Earth City, Mo.; and C-RAM products from Cuming Microwave Corporation of Avon, Massacheusets.

In the embodiment shown in FIGS. 5A and 5B, the RF absorber vias 526 are located in the area directly underneath the die 502. In other embodiments, the RF absorber vias 526 may alternately or additionally be located in one or more adjacent areas of the PCB 504 just outside the periphery of the die 502.

In the embodiment shown in FIGS. 5A and 5B, the RF absorber vias 526 are placed in an irregular pattern, but dispersed fairly evenly beneath the die 502. In other embodiments, some or all of the RF absorber vias 526 may be placed in a more regular (or evenly spaced) pattern, such as a rectangular or hexagonal grid. In still other embodiments, the RF absorber vias 526 may be dispersed less evenly, for example, a first subset being clustered more densely (or more closely together) adjacent to (or under) a region of the die 502 that emits a greater amount of RF energy and a second subset being spaced less densely (or less closely together) under a region of the die 502 that emits a lesser amount of RF energy.

During a recent investigation, a flip-chip that had been shown to be stable when mounted conventionally (i.e., as shown in FIG. 1) was observed to oscillate when placed into a flip configuration (i.e., as shown in FIG. 2). A 3D electromagnetic (EM) simulation was developed including the flip-chip-to-board interface, which was used successfully to model both stable and unstable behavior.

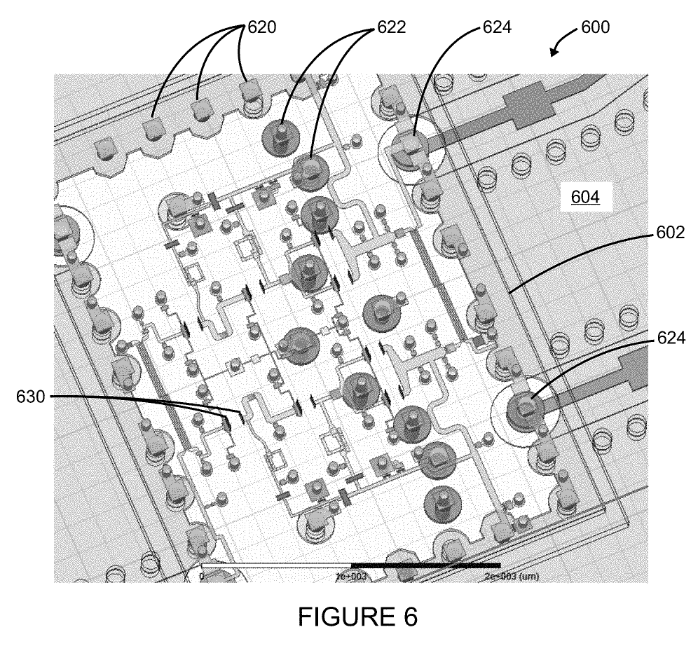

FIG. 6 illustrates an interior view of a system 600 comprising a circuit die 602 and underlying conventional PCB 604, as constructed in the model. The modeled die 602 includes modeled signal and ground connectors 620 electrically coupling the die 602 to the PCB 604. The modeled die 602 also includes modeled RF signal connectors 624 electrically coupling RF signals to and from the die 602 and the PCB 604.

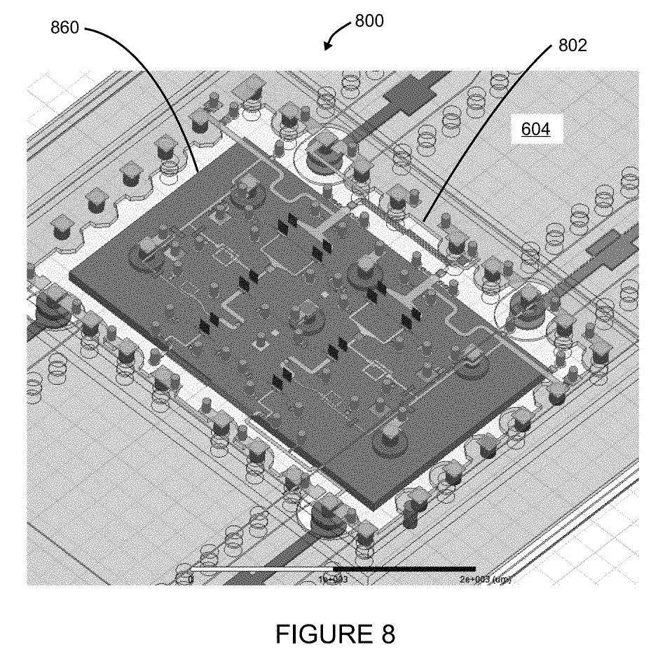

As described above, the die 602 was stable when mounted conventionally, but was observed to oscillate at a frequency of approximately 32 GHz when mounted in a flip-chip configuration. The modeled system 600 (and variants of the model discussed with reference to FIGS. 8-11) was used to investigate techniques for decreasing the undesired RF coupling and feedback discussed with reference to FIG. 4. In a first set of changes, the modeled system 600 includes modeled ideal ground features 630 that were added to break up RF coupling and reflections under flipped die 602. Although they did reduce the undesirable surface currents, as ideal structures, they could not be implemented. Realizable ground features were added to the simulation and were modeled as ground posts 622, but were not as effective as the ideal grounds.

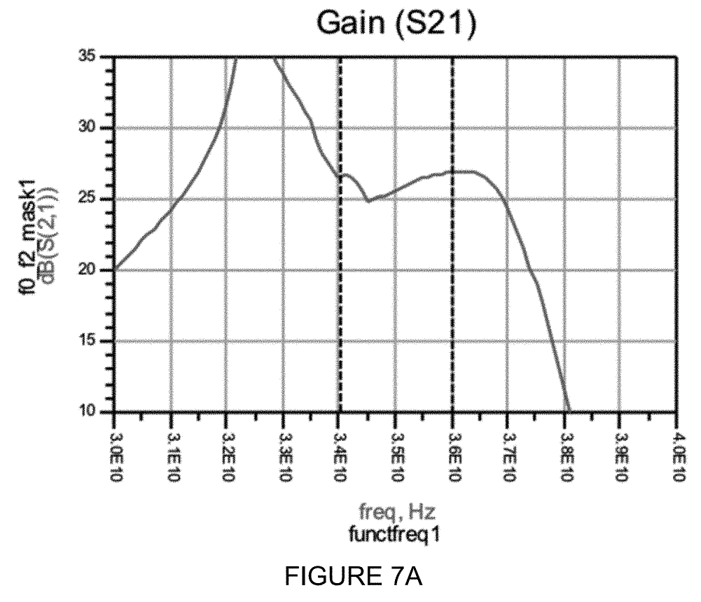

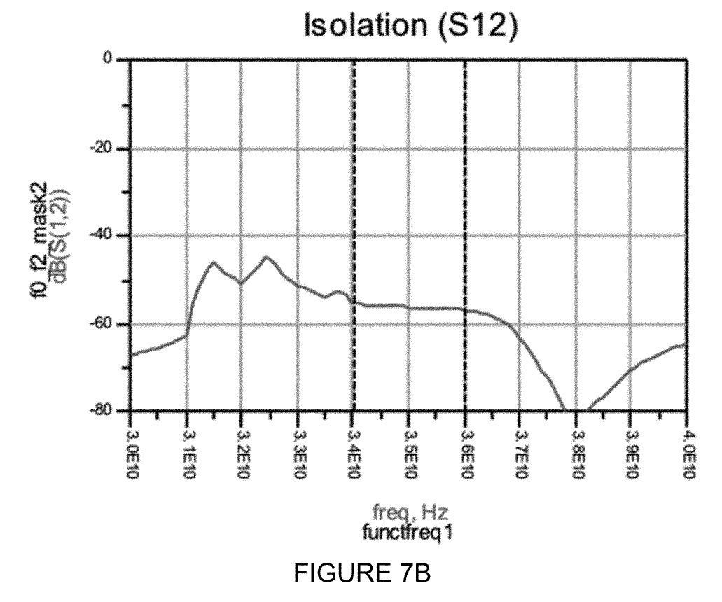

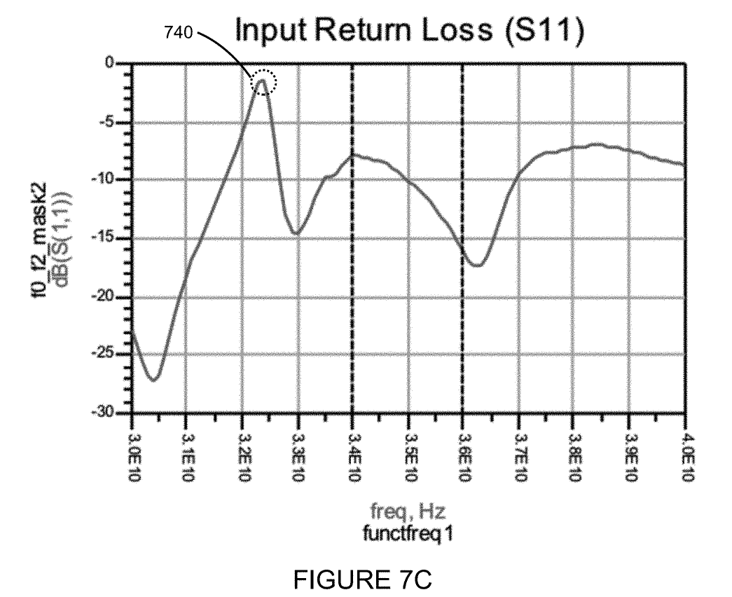

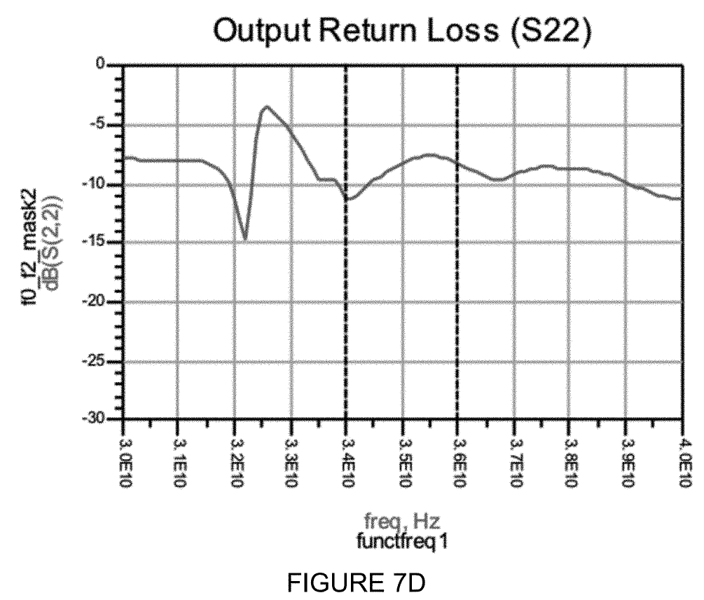

FIG. 7 presents simulated frequency responses of four characteristics of the system of FIG. 6: Gain, Isolation, Input Return Loss, and Output Return Loss. The circuit die 602 is designed for operation in a frequency band of 34-36 GHz, as indicated. As may be seen in FIG. 7, the ground posts provided a slight improvement to the input return loss at about 32.3 GHz (reference character 740). The input return loss at that frequency had been at a positive value (an indicator of oscillation) when the die 602 was modeled without the ground posts 622. However, the improvement shown in FIG. 7 leaves little margin for stability.

While the oscillation frequency of 32.3 GHz is outside the operating band of the circuit die 602 (34-36 GHz), the oscillation still interferes with stable operation of the die 602 in-band (i.e., within its operating band).

FIG. 8 illustrates an interior view of a system 800 (or electronic assembly) according to one embodiment of the disclosure. The system 800 comprises a circuit die 802 and underlying PCB 804 having RF absorber composite 860 formed in a sheet-like shape in a cavity of the PCB 804. The modeled die 802 and PCB 804 include signal, ground, ground post, and RF connectors as described for the system 600 as described with reference to FIG. 6. The modeled sheet 860 of RF absorbent material has the shape of a rectangle and is located within the PCB 804, extending under substantially all active RF circuitry of the die 802. The sheet 860 was modeled as having similar RF absorbent properties to those of the MAST MR11-0039-20 material identified above.

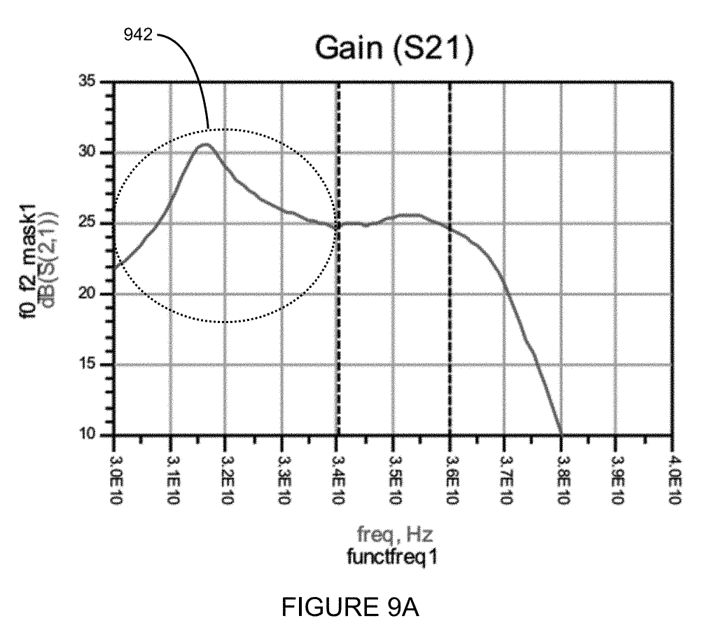

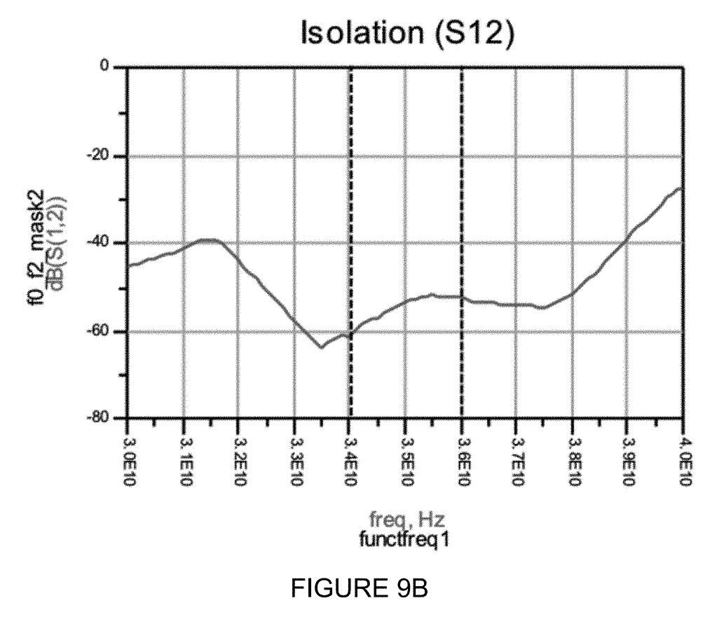

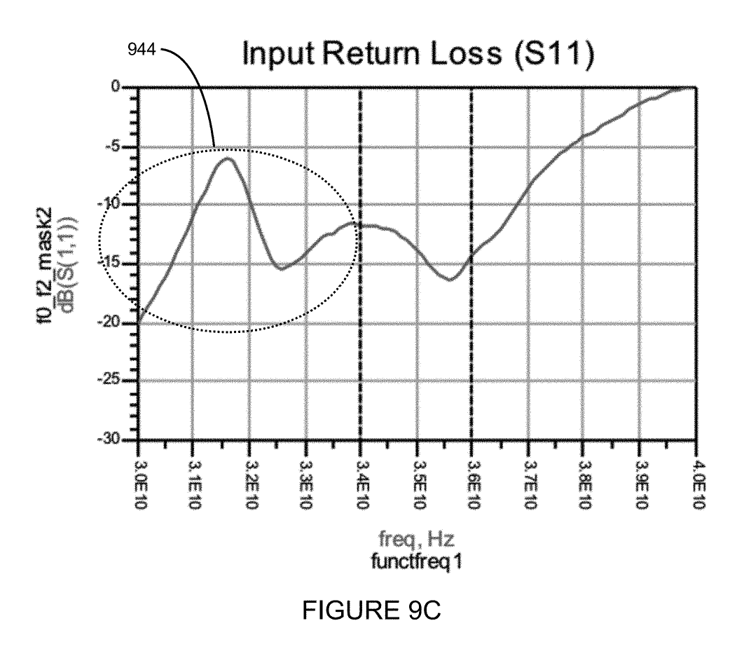

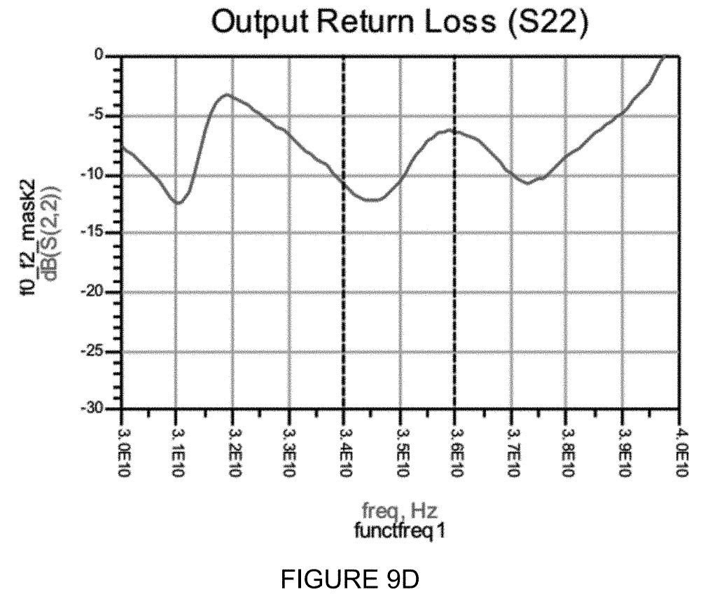

FIG. 9 presents simulated frequency responses of the same four characteristics of the system 800 of FIG. 8 as were presented for the system 600 in FIG. 7. The modeled system 800 showed a reduction in out-of-band gain (942) in the 30-34 GHz range and an improvement in input return loss (944) at the oscillation frequency of 32.3 GHz.

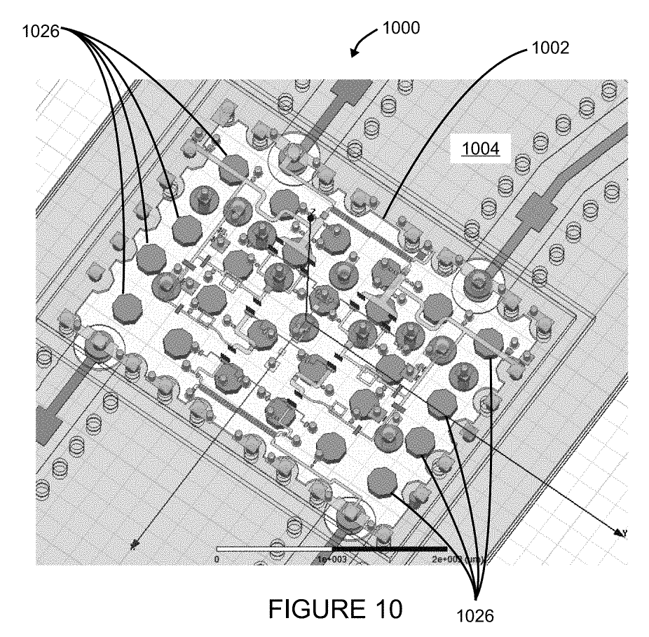

FIG. 10 illustrates an interior view of an electronic assembly 1000 comprising a circuit die 1002 and underlying PCB 1004 according to one embodiment of the disclosure. The PCB 1004 includes RF absorber vias 1026 formed in cavities of the PCB 1004. The simulated vias 1026 are modeled as filled with RF absorber composite comprising resin and RF absorber MAST MR11-0039-20.

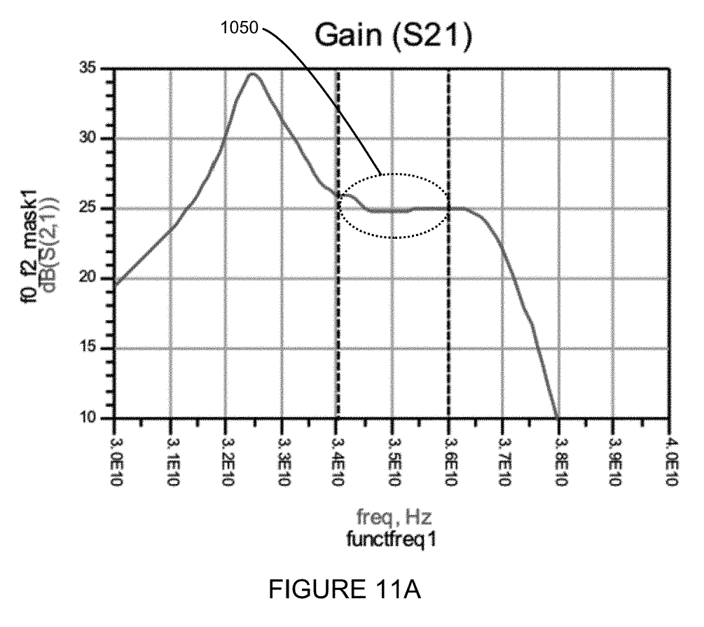

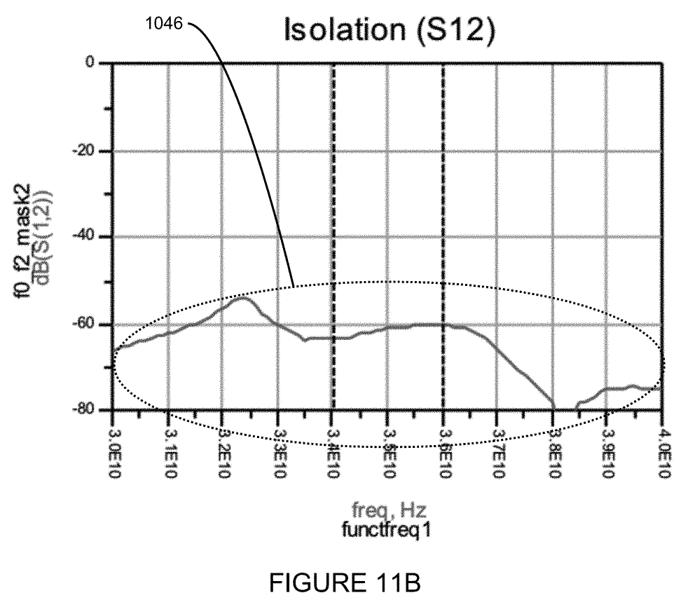

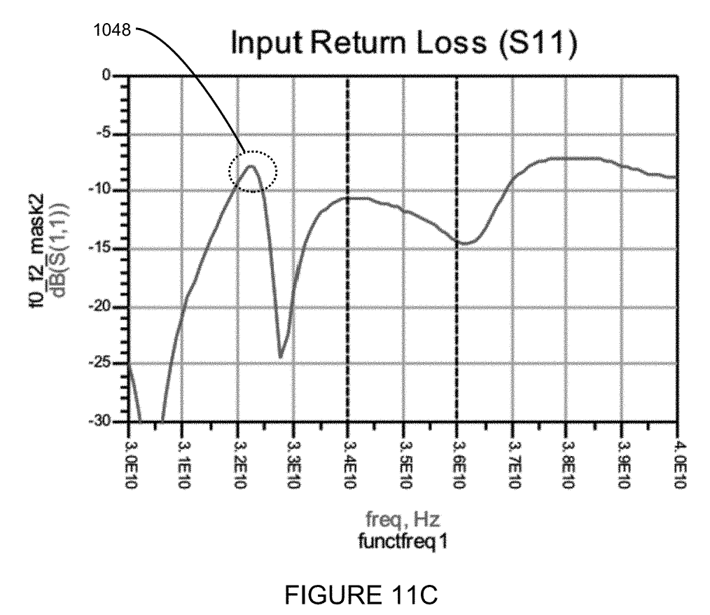

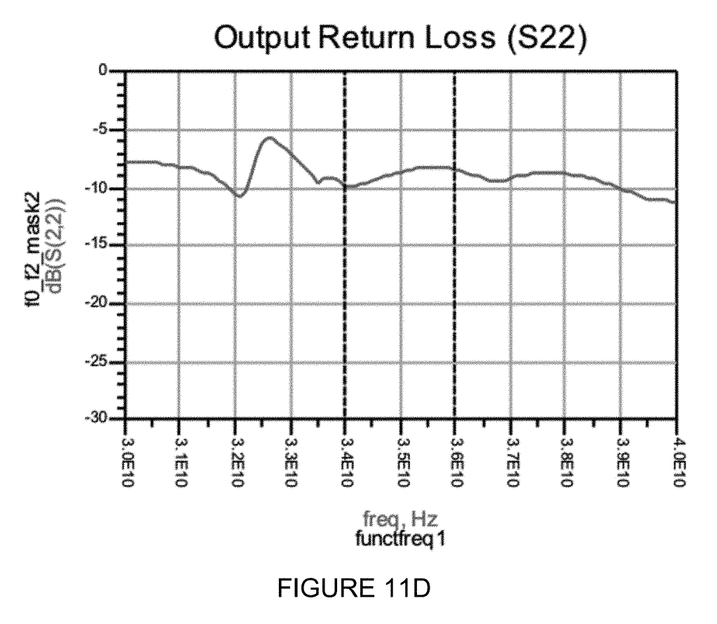

FIG. 11 presents simulated frequency responses of the same four characteristics of the system of FIG. 10 as were presented for the system 600 in FIG. 7 and the system 800 in FIG. 9. The modeled system 1000 shows improved isolation (1046) across the modeled frequency range, 30-40 GHz; improved input return loss (1048) at the oscillation frequency of 32.3 GHz; and improved in-band gain flatness (1050).

In a typical application, RF absorber material works by attenuating a plane wave normal to the surface of the material. Further, a typical RF absorber is fabricated in a thickness that is a desired fraction of the wavelength of the frequency of a signal that is to be attenuated. However, in the flip-chip applications described herein, the distance from the emission of the radiation to the reflective surface on the PCB is small enough as to be in the near field of the die's electromagnetic field.

In various embodiments, an RF absorber material is mixed into a resin or other binder material and forced into a matrix of vias. Preferrably, the diameter of the vias is approximately 10 mil (0.010 inches), to reduce the impact of the RF absorber vias on the routing of traces on the PCB. However in other embodiments, the vias may have larger or smaller diameters. In some embodiments, the size of via is a design choice based upon a type of drilling technique used (laser, mechanical, or other) and a thickness of the dielectric substrate of the PCB. Small vias enable the designer to place vias within the smallest space possible underneath or around the actual circuit elements within the die as may be called for in the simulation of the die within the environment of the board interface.

In still other embodiments, the RF absorber material may be in PCB features other than vias. Such features may have an elongate, ribbon-like shape. In yet other embodiments, the features may be in the shape of a sheet, as shown in FIG. 8. Such a sheet feature may extend beneath only a part of the die, rather than beneath substantially the entire die.

The PCB 504 shown in FIG. 5B is a single substrate PCB, having a substrate with metallic traces or planes applied externally to both sides of the substrate. In the embodiment shown in FIG. 5B, the RF absorber vias 526 extend through the PCB substrate and may be bounded on either or both ends by the metallic traces or planes. Such vias may be characterized as extending through substantially the entire PCB.

In embodiments comprising a multi-layer PCB having two or more substrates, RF absorber features according to the disclosure may extend through fewer than all substrates of the PCB, i.e., through less than the entire depth of the PCB. However, where such a feature extends through all substrates of the multi-layer PCB, the feature may be characterized as extending through substantially the entire PCB.

In some embodiments, a combination of the above described sizes, shapes, and/or depths of RF absorber features may be employed in a single PCB.

Thus, contrary to the typical application in which an RF absorber may be designed in a thickness based on the wavelength of the signal to be attenuated, RF absorber vias are restricted to the thickness of the PCB underlying a circuit die. Therefore, a group of RF absorber vias according to the disclosure are designed to act as a bulk absorber of RF surface currents. This reduces both the conduction and radiation of undesired currents and increases the desired RF isolation.

Embodiments may include electronic assemblies employing high density flip-chip designs, either RF or high speed digital. Embodiments may also provide noise reduction benefits in electronic assemblies employing conventional surface mount integration.

Embodiments of the disclosure allow a flip-chip to be under-filled without interference from RF coupling suppression elements, as the RF absorber vias are incorporated into the PCB substrate itself and do not cover up input and output terminals of the circuit die or PCB. Thus, embodiments of the disclosure provide an advantage in shock and vibration handling while still increasing RF isolation.

Although the present disclosure has been described with one or more exemplary embodiments, various changes and modifications may be suggested to one skilled in the art. It is intended that the present disclosure encompass such changes and modifications as fall within the scope of the appended claims.

What is claimed is:

1. A printed circuit board (PCB) adapted to receive a radio frequency (RF) chip, comprising:
one or more features extending through at least a portion of the depth of the PCB, wherein the one or more features are filled with an RF absorber composite comprising a binder and an RF absorber material, and wherein the one or more features are positioned in the PCB to reduce RF signal coupling between the RF chip and one or more metal surfaces of the PCB.

2. The PCB of claim 1, wherein at least one feature is a via extending through substantially the entire PCB.

3. The PCB of claim 2, wherein the via has a diameter of approximately 10 mil.

4. The PCB of claim 1, wherein at least one feature comprises one of a sheet and a ribbon of RF absorber composite.

5. The PCB of claim 1, wherein the PCB comprises a plurality of features and at least some of the features are arranged in a regular pattern.

6. The PCB of claim 1, wherein the PCB comprises a plurality of features and a first subset of the plurality of features are spaced more densely than a second subset of the plurality of features.

7. The PCB of claim 6, wherein the first subset is located adjacent to a first region of the RF chip and the second subset is located adjacent to a second region of the RF chip, where the first region of the RF chip emits a greater amount of RF energy than the second region of the RF chip.

8. An electronic assembly, comprising:
a printed circuit board (PCB); and
a radio frequency (RF) chip, mounted to the PCB in a flip-chip configuration,
wherein the PCB comprises one or more features extending through at least a portion of the depth of the PCB, wherein the one or more features are filled with an RF absorber composite comprising a binder and an RF absorber material, and wherein the one or more features are positioned in the PCB to reduce RF signal coupling between the RF chip and one or more metal surfaces of the PCB.

9. The electronic assembly of claim 8, wherein at least one feature is a via extending through substantially the entire PCB.

10. The electronic assembly of claim 9, wherein the via has a diameter of approximately 10 mil.

11. The electronic assembly of claim 8, wherein at least one feature comprises one of a sheet and a ribbon of RF absorber composite.

12. The electronic assembly of claim 8, wherein the PCB comprises a plurality of features and at least some of the features are arranged in a regular pattern.

13. The electronic assembly of claim 8, wherein the PCB comprises a plurality of features and a first subset of the plurality of features are spaced more densely than a second subset of the plurality of features.

14. The electronic assembly of claim 13, wherein the first subset is located adjacent to a first region of the RF chip and the second subset is located adjacent to a second region of the RF chip, where the first region of the RF chip emits a greater amount of RF energy than the second region of the RF chip.

15. A method for fabricating a printed circuit board (PCB) for use with a radio frequency (RF) chip, the method comprising:
forming one or more cavities in at least one substrate of a PCB; and
filling the one or more cavities with an RF absorber composite comprising a binder and an RF absorber material,
wherein the one or more cavities are positioned in the PCB substrate to reduce RF signal coupling between the RF chip and one or more metal surfaces of the PCB.

16. The method of claim 15, wherein at least one cavity is a via extending through substantially the entire PCB.

17. The method of claim 16, wherein the via has a diameter of approximately 10 mil.

18. The method of claim 15, wherein the step of forming comprises forming a plurality of cavities in the PCB, where at least some of the features are arranged in a regular pattern.

19. The method of claim 15, wherein the step of forming comprises forming a plurality of cavities in the PCB, where a first subset of the plurality of cavities are spaced more densely than a second subset of the plurality of cavities.

20. The method of claim 19, wherein the step of forming further comprises forming the first subset in a first region of the PCB located adjacent to a first region of the RF chip and forming the second subset in a second region of the PCB located adjacent to a second region of the RF chip, where the first region of the RF chip emits a greater amount of RF energy than the second region of the RF chip.
